(19) United States
(12) Patent Application Publication
(10) Pub. No.: US 2008/0056427 A1
(43) Pub. Date: Mar. 6, 2008

(54) Telecommunications Systems

(76) Inventors: Rob Bristow, Hants (GB); Lars Jonsson, Sodra Sandby (SE); Thomas Mattsson, Limhamn (SE)

Correspondence Address: ERICSSON INC., 6300 LEGACY DRIVE, M/S EVR 1-C-11, PLANO, TX, 75024, US

(21) Appl. No.: 10/597,292

(22) PCT Filed: Nov. 23, 2004
(86) PCT No.: PCT/GB04/04923

§ 371 Date: May 10, 2007

(30) Foreign Application Priority Data
Jan. 21, 2004 (EP) 04250308-6

(51) Int. Cl. H03L 7/06; H04B 1/16

(52) U.S. Cl. 375/376; 455/265

(57) ABSTRACT

A reference frequency generator circuit for a radio frequency transmit and receive apparatus comprises: a first voltage controlled oscillator which is operable to produce a first reference frequency signal, a second voltage controlled oscillator which is operable to produce a second reference frequency signal, a switchable set of dividers, connected to receive the first and second reference frequency signals, and operable to produce a set of output reference frequency signals therefrom, a first subset of the set of output reference frequencies being derived from the first reference frequency, and a second subset of the set of output reference frequencies being derived from the second reference frequency, wherein the first and second reference frequency signals are not equal in frequency to the output reference frequency signals in the set of output reference frequency signals.

### The present invention relates to mobile telecommunications systems, and, in particular, to systems for generating reference frequency signals in mobile telecommunications systems.

### BACKGROUND OF THE INVENTION

In mobile telecommunications systems of the GSM type, it is necessary to be able to transmit and receive on four common frequency bands—850, 900, 1800 and 1900 MHz. This requires frequency sources in the region of 900 MHz and 1800 MHz.

Typically, current frequency sources use three different voltage controlled oscillators (VCOs), operating at about 1, 2 and 4 GHz. The VCOs used for transmission operate on the same frequency as the required transmit channel and the VCOs used for reception operate at twice the required receive frequency to allow use of a well known digital divider circuit to provide in-phase and quadrature local oscillator (LO) signals.

However, when implemented in an application specific integrated circuit (ASIC), the silicon area of the IC used by the 1 and 2 GHz VCOs has a significant upward impact on the cost of the ASIC. Also, there are significant problems with feedback to these VCOs since they operate at the same frequency as the transmitter signal.

In one known previously-considered example, all of the required frequencies are generated using a single VCO combined with frequency divider circuits; for example the VCO could operate in the region of 4 GHz and be divided by 2 or 4 as required to provide the lower frequencies. However, this is not a straightforward technique to use in an ASIC as the required tuning range of the VCO is large.

### SUMMARY OF THE PRESENT INVENTION

According to the present invention, there is provided a reference frequency generator circuit for a radio frequency transmit and receive apparatus, the circuit comprising: a first voltage controlled oscillator which is operable to produce a first reference frequency signal, a second voltage controlled oscillator which is operable to produce a second reference frequency signal, a switchable set of dividers, connected to receive the first and second reference frequency signals, and operable to produce a set of output reference frequency signals therefrom, a first subset of the set of output reference frequencies being derived from the first reference frequency, and a second subset of the set of output reference frequencies being derived from the second reference frequency, wherein the first and second reference frequency signals are not equal in frequency to the output reference frequency signals in the set of output reference frequency signals.

### BRIEF DESCRIPTION OF THE DRAWINGS

FIG. 1 illustrates a first embodiment of the present invention;

FIG. 2 illustrates a second embodiment of the present invention;

FIG. 3 illustrates a third embodiment of the present invention; and

FIG. 4 illustrates ranges of reference frequencies provided by VCOs used in embodiments of the present invention.

### DETAILED DESCRIPTION OF THE PREFERRED EMBODIMENTS

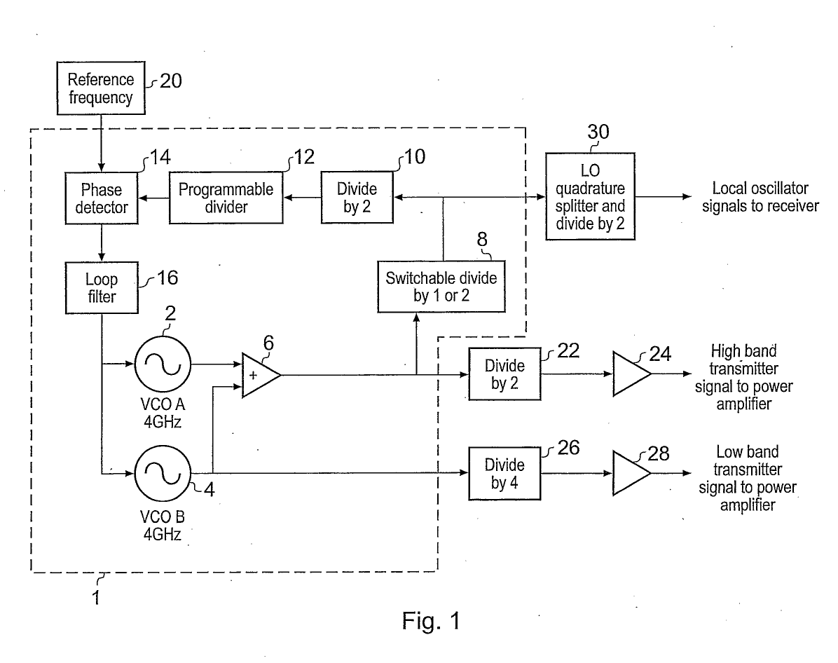

FIG. 1 illustrates a first embodiment of the present invention, for providing transmitter and receiver signals suitable for use in a mobile station (MS) for use in a mobile telecommunications network. The embodiment of FIG. 1 comprises a phase lock loop circuit (PLL) comprising first and second voltage controlled oscillators (VCOA, VCOB) 2 and 4. The VCOs 2 and 4 provide output signals to an adder 6 which supplies a signal to a switchable divider 8. As will be explained in more detail below, the VCOs 2 and 4 are used independently, and so the output of the adder 6 is equivalent to the output of the chosen operating VCO. The switchable divider 8 is operable to divide the signal from the adder 6 by one or two. The output of the switchable divider 8 is supplied to a further divider 10, which is operable to divide the signal by 2. The output of the divider 10 is supplied to a programmable divider 12. The programmable divider 12 supplies an output to a phase detector 14 for comparison with a reference frequency 20. The output of the phase detector 14 is supplied to a loop filter 16, which in turn supplies a filtered control signal to each of the first and second VCOs 2 and 4. The PLL operates to stabilise the outputs of the VCOs 2 and 4, in known manner. In embodiments of the present invention the VCO is operated at 2× or 4× the desired frequency, and there is always a fixed division of 2 or 4 provided by the dividers 10 and 8. This means that the frequency provided to the input of the programmable divider is the same as if the VCO were operating at the required frequency and divider 10 and 8 were not present.

The programmable divider 12 operates to lock the operating VCO to twice or four times the required output frequency of Npd*Fref, where Npd is the programmable divider modulus and Fref is the reference frequency.

The fixed and programmable dividers provide a set of dividers which are used to tailor the output of the VCOs. The modulus (size) of the divider (eg. /2 or /4) can be fixed or varying. If varying appropriately, the VCOs can be frequency modulated. The varying modulus can be provided by a varying signal or by a suitable combination of varying and fixed signals. For example, the modulus may vary around a fixed point. l.

The output of the second VCO 4 is also supplied to a divider 26, which is operable to divide the output of the VCO by 4. The output of the divider is supplied, via a buffer 28, to a power amplifier (not shown) of the mobile station and provides the low band transmitter signal frequency. In a similar manner, the output of the adder 6 is supplied to a divider 22 which operates to divide that summed signal by 2. The divided signal is supplied, via a buffer 24, to the power amplifier of the mobile station. This provides the high band transmitter signal frequency.

In the example embodiment shown in FIG. 1, the VCOs 2 and 4 are both tuned to output signals of around 4 GHz, so that the high band transmitter signal frequency is 2 GHz and the low band 1 GHz.

The circuit is also operable to provide the local oscillator (LO) signals to the mobile station receiver (not shown), and this is achieved by supplying the output of the switchable divider 8 to a quadrature splitter and divider 30. The quadrature splitter and divider 30 is operable to produce a signal which is half the frequency of the input signal, and has inphase and quadrature signals for supply to the receiver.

In the examples given, the divider 30 has a single output connection which carries the LO signal at either around 1 GHz or around 2 GHz. This is possible only if the receiver's mixer has enough bandwidth to handle both these bands. If this is not the case, then respective receivers can be used for the bands, with the LO signal split and routed to those receivers as required.

It is a feature of the invention that the characteristics of the frequency modulation as measured at the input to the programmable divider and also at the output of the circuit (24, 28) are dictated by Npd in exactly the same way as if the VCO was operated at the required final frequency and the fixed dividers 10, 8, 22 and 26 were omitted. Clearly, the frequency modulation measured at the outputs of the VCOs will not be correct—peak deviations of the FM modulation will be twice or four times the required values. It is an advantage of an embodiment of the present invention that the modulated signal at input of programmable divider is defined by variations in Npd produces exactly the same result as for a conventional technique with the VCO equal to the final frequency.

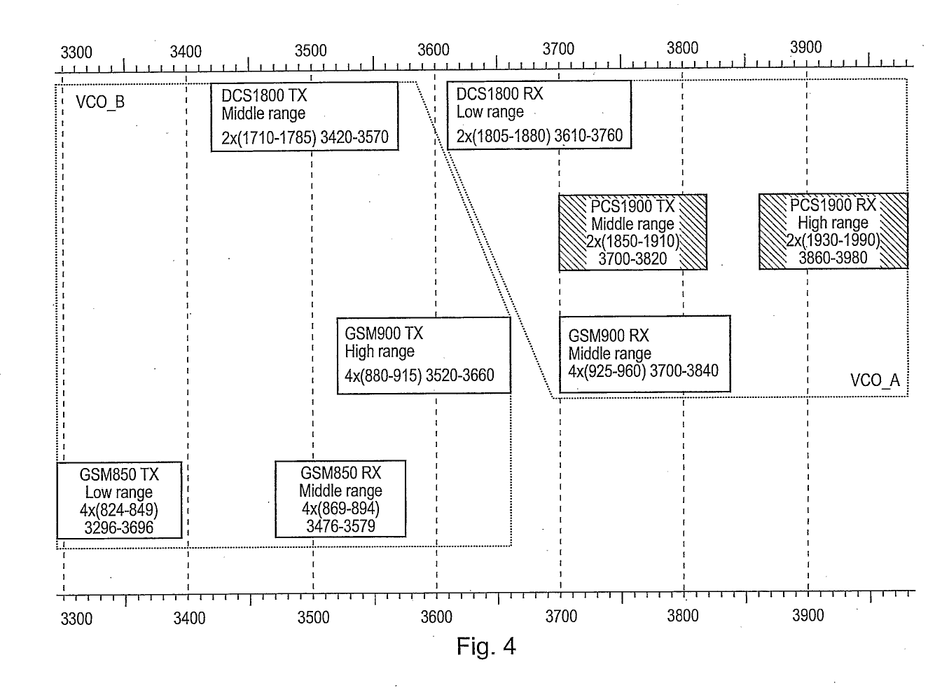

The allocation of bands of operation between VCOA and VCOB can be arranged so as to minimise the tuning range required of each VCO. FIG. 4 illustrates that VCO A (2) is used for the reference frequencies for systems around 3600 Mhz to 4000 Mhz, and VCO B for the range around 3300 Mhz to 3650 Mhz.

The loop dynamics of the PLL will be affected by the fixed divider in such a way as to reduce the open loop gain by 2 or 4. This is not usually significant though because the tuning sensitivity of the 4 GHz VCO is usually approximately twice or 4 times that of a 2 or 1 GHz VCO respectively, so the overall loop gain with embodiments of the present invention is not changed significantly.

Embodiments of the present invention can therefore provide two VCOs (2 and 4) that cover the entire required tuning range. The programmable divider of the phase locked loop circuit is presented with a signal at the same frequency as the required frequency (ie. nominally the centre frequency of the GSM channel concerned) so that the circuit behaves as if the VCO was operating at the required frequency instead of a multiple of 2 or 4 times.

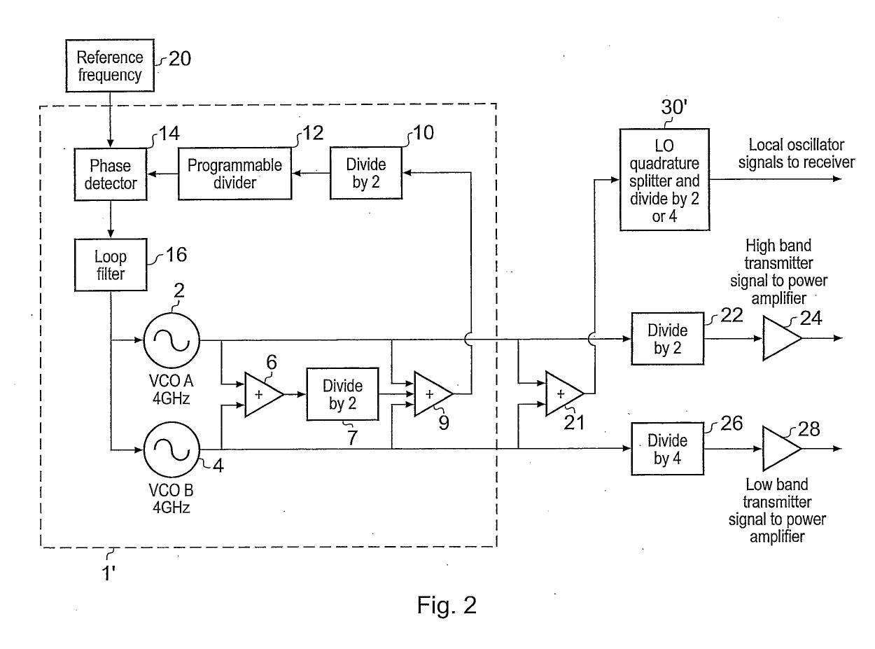

FIG. 2 illustrates an alternative circuit layout, in which switchable divider 8 is provided by a fixed divider (÷2) 7 and gates 9 and 21. The gates operate to select an input signal to be transferred to the rest of the circuit. The signal routes from the VCOs 2 and 4 are determined by switching the gates 6, 9, 21, such that the correct VCO is used for the transmit/receive frequencies in use.

The FIG. 2 layout gives advantages in terms of circuit layout and size.

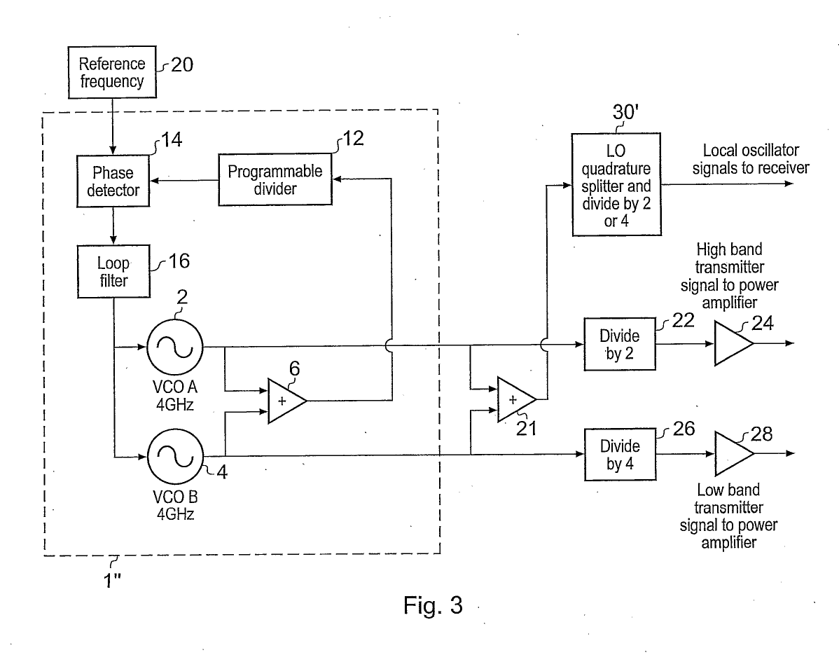

FIG. 3 shows a further enhancement, where the PLL actually operates at the VCO frequency, ie. 4 GHz. In the case of a fractional-N PLL this allows the resolution of the divided down signals to be higher by a factor 2 or 4.

By using this technique the tuning range of the VCOs is relatively small and easy to implement, and the small size of 4 GHz circuits allows significant cost saving relative to the 1 GHz VCOs. In addition the frequency of the VCO is different from the final output frequency, which gives benefits in reducing the coupling effects between the output signal and the VCOs. This has the benefit of maintaining control compatibility between different architectures.

What is claimed is:

1.-5. (canceled)

6. A phase locked loop circuit for a radio frequency transmit and receive apparatus, the circuit comprising:
a first voltage controlled oscillator which is operable to produce a first reference frequency signal;
a second voltage controlled oscillator which is operable to produce a second reference frequency signal;
a switchable set of dividers, coupled to receive the first and second reference frequency signals, and operable to produce a set of output reference frequency signals therefrom, a first subset of the set of output reference frequencies being derived from the first reference frequency, and a second subset of the set of output reference frequencies being derived from the second reference frequency; and
a voltage controlled oscillator (VCO) control means coupled to receive an external reference signal and a feedback signal, and operable to supply a control voltage to the first and second voltage controlled oscillators in dependence upon received external reference and feedback signals, so as to maintain desired first and second reference frequency signals;
wherein the first and second reference frequency signals are not equal in frequency to the output reference frequency signals in the set of output reference frequency signals; and
wherein the set of dividers comprises:
a first divider for selectively receiving the first or second reference frequency signals, and for producing a high band output reference frequency signal for a transmitter;
a second divider for receiving the second reference frequency signal and for producing a low band output reference frequency signal for the transmitter; and
a third divider for selectively receiving the first or second reference frequency signals and for producing local oscillator output reference frequency signals for a receiver, and for producing a feedback signal for supply to the VCO control means.

7. The circuit of claim 6, wherein the set of dividers is operable to vary a modulus value thereof, thereby causing the first and second voltage controlled oscillators to be frequency modulated.

8. The circuit of claim 7, wherein the modulus value has a fixed portion and a time-varying portion.

9. The circuit of claim 8, wherein the set of output reference frequency signals have frequencies corresponding to frequencies required for GSM850, GSM900, DCS1800 and PCS1900 mobile telecommunications standards.

10. The circuit of claim 9, wherein the first and second voltage controlled oscillators are selectively controlled by a phase locked loop.

11. The circuit of claim 7, wherein the first and second voltage controlled oscillators are selectively controlled by a phase locked loop.

12. The circuit of claim 11, wherein the set of output reference frequency signals have frequencies corresponding to frequencies required for GSM850, GSM900, DCS1800 and PCS1900 mobile telecommunications standards.

13. The circuit of claim 12, wherein the set of dividers is operable to vary a modulus value thereof, thereby causing the first and second voltage controlled oscillators to be frequency modulated.

14. The circuit of claim 13, wherein the modulus value has a fixed portion and a time-varying portion.

15. The circuit of claim 6, wherein the first and second voltage controlled oscillators are selectively controlled by a phase locked loop.

16. The circuit of claim 15, wherein the set of dividers is operable to vary a modulus value thereof, thereby causing the first and second voltage controlled oscillators to be frequency modulated.

17. The circuit of claim 16, wherein the modulus value has a fixed portion and a time-varying portion.

18. The circuit of claim 17, wherein the set of output reference frequency signals have frequencies corresponding to frequencies required for GSM850, GSM900, DCS1800 and PCS1900 mobile telecommunications standards.

19. The circuit of claim 6, wherein the set of output reference frequency signals have frequencies corresponding to frequencies required for GSM850, GSM900, DCS1800 and PCS1900 mobile telecommunications standards.

20. A method for use in phase locked loop circuit of a radio frequency transmit and receive apparatus, the method comprising the steps of:
producing a first reference frequency signal by a first voltage controlled oscillator;
producing a second reference frequency signal by a second voltage controlled oscillator;
receiving, by a switchable set of dividers, the first and second reference frequency signals, and producing a set of output reference frequency signals therefrom;
deriving a first subset of the set of output reference frequencies from the first reference frequency, and a second subset of the set of output reference frequencies from the second reference frequency, and
receiving, from a voltage controlled oscillator (VCO) control means, an external reference signal and a feedback signal operable to supply a control voltage to the first and second voltage controlled oscillators in dependence upon received external reference and feedback signals, so as to maintain desired first and second reference frequency signals, wherein the first and second reference frequency signals are not equal in frequency to the output reference frequency signals in the set of output reference frequency signals, and
the set of dividers further performing the steps of:
selectively receiving, by a first divider, the first or second reference frequency signals, and producing a high band output reference frequency signal for a transmitter;
selectively receiving, by a second divider, the second reference frequency signal and producing a low band output reference frequency signal for the transmitter; and
selectively receiving, by a third divider, the first or second reference frequency signals and producing local oscillator output reference frequency signals for a receiver, and producing a feedback signal for supply to the VCO control means.

21. The method of claim 20, further comprising the step of varying, by the set of dividers, a modulus value thereof, thereby causing the first and second voltage controlled oscillators to be frequency modulated.

22. The method of claim 21, wherein the modulus value has a fixed portion and a time-varying portion.

23. The method of claim 22, wherein the set of output reference frequency signals have frequencies corresponding to frequencies required for GSM850, GSM900, DCS1800 and PCS1900 mobile telecommunications standards.

24. The method of claim 20, further comprising the step of selectively controlling the first and second voltage controlled oscillators by a phase locked loop.
